(19) United States
(12) Patent Application Publication
(10) Pub. No.: US 2024/0047418 A1
(43) Pub. Date: Feb. 8, 2024

(54) SEMICONDUCTOR PACKAGE

(71) Applicant: Samsung Electronics Co., Ltd., Suwon-si (KR)

(72) Inventors: Choongbin YIM, Suwon-si (KR); Gitae Park, Suwon-si (KR); Jinwoo Park, Suwon-si (KR)

(21) Appl. No.: 18/199,553

(22) Filed: May 19, 2023

(30) Foreign Application Priority Data
Aug. 5, 2022 (KR) 10-2022-0098124

(51) Int. Cl. H01L 25/065; H01L 23/498; H01L 25/18; H10B 80/00; H01L 23/31; H01L 23/538; H01L 23/00

(52) U.S. Cl. CPC H01L 25/0652; H01L 23/49827; H01L 25/18; H10B 80/00; H01L 23/49833; H01L 23/3157; H01L 23/49816; H01L 23/5386; H01L 24/16; H01L 2924/1435; H01L 2924/1431; H01L 2924/181; H01L 2224/16227

(57) ABSTRACT

A semiconductor package includes: a redistribution layer including a plurality of redistribution patterns; a sub-semiconductor package including a sub-semiconductor package substrate and a first semiconductor chip that is on the sub-semiconductor package substrate, wherein the sub-semiconductor package substrate is on the redistribution layer and includes a plurality of first lower surface pads; and a second semiconductor chip on the redistribution layer and spaced apart from the sub-semiconductor package in a horizontal direction, wherein the second semiconductor chip includes a chip pad, wherein at least some of the plurality of redistribution patterns of the redistribution layer are overlapped with and electrically connected to the plurality of first lower surface pads of the sub-semiconductor package, respectively.

### CROSS-REFERENCE TO RELATED APPLICATION

This application claims priority under 35 U.S.C. § 119 to Korean Patent Application No. 10-2022-0098124, filed on Aug. 5, 2022, in the Korean Intellectual Property Office, the disclosure of which is incorporated by reference herein in its entirety.

### TECHNICAL FIELD

The inventive concept relates to a semiconductor package, and more particularly, to a semiconductor package including a redistribution layer.

### DISCUSSION OF THE RELATED ART

Along with the rapid development of the electronics industry and in response to demands of users, electronic devices have been further miniaturized, been made multi-functional, and been made with increased capacity, such as storage capacity. Accordingly, a semiconductor package including a plurality of semiconductor chips has been under development. For example, a method of mounting several types of semiconductor chips side-by-side on a package substrate or stacking semiconductor chips or packages on a package substrate is under development.

### SUMMARY

According to an embodiment of the present inventive concept, a semiconductor package includes: a redistribution layer including a plurality of redistribution patterns; a sub-semiconductor package including a sub-semiconductor package substrate and a first semiconductor chip that is on the sub-semiconductor package substrate, wherein the sub-semiconductor package substrate is on the redistribution layer and includes a plurality of first lower surface pads; and a second semiconductor chip on the redistribution layer and spaced apart from the sub-semiconductor package in a horizontal direction, wherein the second semiconductor chip includes a chip pad, wherein at least some of the plurality of redistribution patterns of the redistribution layer are in direct contact with and electrically connected to the plurality of first lower surface pads of the sub-semiconductor package, respectively.

According to an embodiment of the present inventive concept, a semiconductor package includes: a redistribution layer including a plurality of redistribution patterns; a sub-semiconductor package including a sub-semiconductor package substrate and a first semiconductor chip that is on the sub-semiconductor package substrate and that includes a plurality of second lower surface pads, wherein the sub-semiconductor package substrate is on the redistribution layer and includes a plurality of first lower surface pads and a plurality of first upper surface pads; a second semiconductor chip on the redistribution layer and spaced apart from the sub-semiconductor package in a horizontal direction, wherein the second semiconductor chip includes a plurality of third lower surface pads; and a molding layer on the redistribution layer and at least partially surrounding a side surface of each of the sub-semiconductor package and the second semiconductor chip, wherein at least some of the plurality of redistribution patterns of the redistribution layer are in direct contact with and electrically connected to the plurality of first lower surface pads of the sub-semiconductor package, respectively.

According to an embodiment of the present inventive concept, a semiconductor package includes: a redistribution layer including a plurality of redistribution lower pads, a plurality of redistribution line patterns, and a plurality of conductive vias; a sub-semiconductor package including a sub-semiconductor package substrate and a first semiconductor chip that is on the sub-semiconductor package substrate and that includes a plurality of second lower surface pads, wherein the sub-semiconductor package substrate is on the redistribution layer and includes a plurality of first lower surface pads and a plurality of first upper surface pads; a plurality of first connection terminals between the plurality of first upper surface pads and the plurality of second lower surface pads; a second semiconductor chip on the redistribution layer and spaced apart from the sub-semiconductor package in a horizontal direction, wherein the second semiconductor chip includes a plurality of third lower surface pads; and a molding layer on the redistribution layer and at least partially surrounding a side surface of each of the sub-semiconductor package and the second semiconductor chip, wherein at least some of the plurality of conductive vias of the redistribution layer are in direct contact with and electrically connected to the plurality of first lower surface pads of the sub-semiconductor package, respectively, and wherein the sub-semiconductor package includes a land grid array (LGA) substrate.

### BRIEF DESCRIPTION OF THE DRAWINGS

The above and other aspects of the present inventive concept will become more apparent by describing in detail embodiments thereof, with reference to the accompanying drawings, in which:

FIG. 1 is a cross-sectional view of a semiconductor package according to an embodiment of the present inventive concept;

FIG. 2 is a cross-sectional view of a semiconductor package according to an embodiment of the present inventive concept;

FIG. 3 is a cross-sectional view of a semiconductor package according to an embodiment of the present inventive concept;

FIG. 4 is a cross-sectional view of a semiconductor package according to an embodiment of the present inventive concept;

FIG. 5 is a cross-sectional view of a semiconductor package according to an embodiment of the present inventive concept;

FIG. 6 is a cross-sectional view of a semiconductor package according to an embodiment of the present inventive concept;

FIGS. 7A, 7B, 7C, 7D, 7E, and 7F are cross-sectional views illustrating a method of manufacturing a semiconductor package, according to an embodiment of the present inventive concept; and

FIGS. 8A, 8B and 8C are cross-sectional views illustrating a method of manufacturing a semiconductor package, according to an embodiment of the present inventive concept.

### DETAILED DESCRIPTION OF THE EMBODIMENTS

Hereinafter, embodiments of the present inventive concept are described in detail with reference to the accompanying drawings. Like reference numerals in the drawings denote like elements throughout the drawings, and thus their repetitive descriptions may be omitted or briefly discussed.

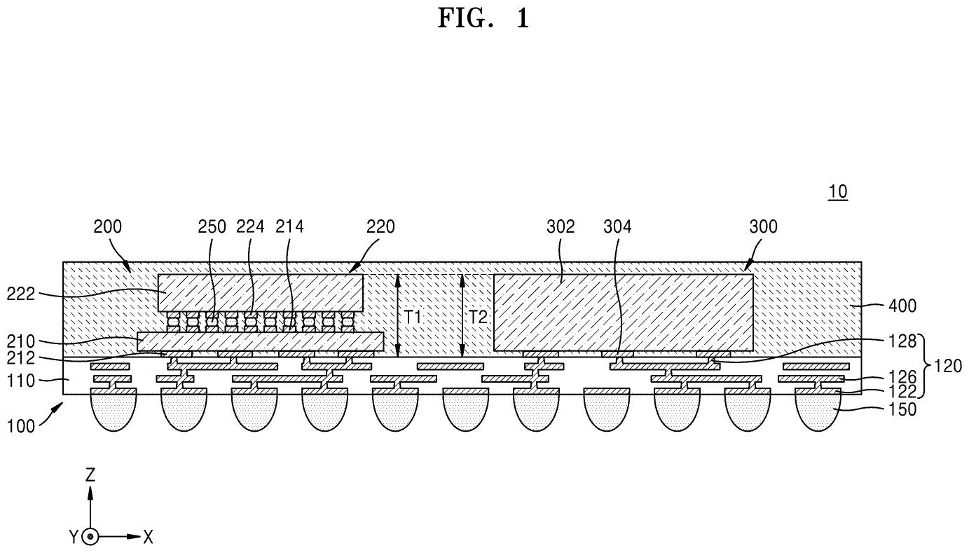

FIG. 1 is a cross-sectional view of a semiconductor package 10 according to an embodiment of the present inventive concept.

Referring to FIG. 1, the semiconductor package 10 may include a redistribution layer 100, a sub-semiconductor package 200 disposed on the redistribution layer 100 and including a first semiconductor chip 220, a second semiconductor chip 300 spaced apart from the sub-semiconductor package 200 in a horizontal direction (e.g., an X direction and/or a Y direction), and a molding layer 400 disposed on the redistribution layer 100 and at least partially surrounding a side surface of the sub-semiconductor package 200 and a side surface of the second semiconductor chip 300. Although FIG. 1 shows that the semiconductor package 10 includes one sub-semiconductor package 200 and one second semiconductor chip 300, this is only illustrative, and the present inventive concept is not limited thereto. In an embodiment of the present inventive concept, the semiconductor package 10 may include a plurality of sub-semiconductor packages 200 and/or a plurality of second semiconductor chips 300.

In the specification, a direction parallel to a main surface of the redistribution layer 100 may be referred to as the horizontal direction (the X direction and/or the Y direction), and a direction substantially perpendicular to the main surface may be referred to as a vertical direction (e.g., a Z direction).

The redistribution layer 100 may be disposed beneath the sub-semiconductor package 200 and the second semiconductor chip 300, and the redistribution layer 100 may redistribute to an external area of a plurality of first lower surface pads 212 of the sub-semiconductor package 200. For example, signals may be redistributed to and from the plurality of first lower surface pads 212 of the sub semiconductor package 200 through the redistribution layer 100. For example, the redistribution layer 100 may include a redistribution insulating layer 110 and a plurality of redistribution patterns 120.

The redistribution insulating layer 110 may be formed of an insulating material, e.g., photo-imageable dielectric (PID) resin, and may further include photosensitive polyimide and/or an inorganic filler. The redistribution insulating layer 110 may have a multi-layer structure according to a multi-layer structure of the plurality of redistribution patterns 120. However, for convenience, FIG. 1 shows that the redistribution insulating layer 110 has a single-layer structure. If the redistribution insulating layer 110 has a multi-layer structure, the redistribution insulating layer 110 may be formed of the same material or different materials.

The plurality of redistribution patterns 120 may transfer an electrical signal and/or heat inside the semiconductor package 10. Each of the plurality of redistribution patterns 120 may include a redistribution lower pad 122, a redistribution line pattern 126, and a conductive via 128. For example, the plurality of redistribution patterns 120 may include a metal, such as copper (Cu), aluminum (Al), tungsten (W), titanium (Ti), tantalum (Ta), indium (In), molybdenum (Mo), Manganese (Mn), cobalt (Co), tin (Sn), nickel (Ni), magnesium (Mg), rhenium (Re), beryllium (Be), gallium (Ga), or ruthenium (Ru), or an alloy thereof but are not limited thereto.

A photosensitive insulating material may undergo an exposure process and a development process to produce a plurality of redistribution line patterns 126 and a plurality of conductive vias 128. In an embodiment of the present inventive concept, the plurality of redistribution patterns 120 may be formed by stacking a metal or an alloy of the metal on a seed layer including Ti, titanium nitride, and/or TiW.

The plurality of redistribution line patterns 126 may be on at least one of upper and lower surfaces of the redistribution insulating layer 110, in the specification, a lower surface of a certain component may refer to a surface relatively close to an external connection terminal 150 among two surfaces spaced apart from each other in a vertical direction (e.g., the Z direction), and an upper surface of the certain component may refer to a surface opposite to the lower surface. The plurality of conductive vias 128 may be in contact with and connected to some of the plurality of redistribution line patterns 126, respectively, by passing through the redistribution insulating layer 110. In an embodiment of the present inventive concept, at least some of the plurality of redistribution line patterns 126 may be formed and integrated with some of the plurality of conductive vias 128. For example, a redistribution line pattern 126 and a conductive via 128 in contact with an upper surface of the redistribution line pattern 126 may be integrated by one body; however, the present inventive concept is not limited thereto.

The plurality of redistribution patterns 120 including the plurality of redistribution line patterns 126 and the plurality of conductive vias 128 nay be formed by plating. For example, the plurality of redistribution patterns 120 may be formed by plating, such as immersion plating, electroless plating, or electroplating.

The conductive via 128 may be configured to transfer an electrical signal and/or heat inside the semiconductor package 10. The conductive via 128 may include a metal, such as Mo, Mn, Co, Sn, Ni, Mg, Re, Be, Ga, or Ru, or an alloy thereof, but the present inventive concept is not limited thereto. A photosensitive insulating material may undergo an exposure process and a development process to produce the conductive via 128.

In an embodiment of the present inventive concept, the plurality of conductive vias 128 may have a tapered shape where a horizontal width thereof gradually decreasing from a lower side to an upper side thereof. For example, the plurality of conductive vias 128 may have a horizontal width gradually increasing away in the vertical direction (e.g., the Z direction) from the sub-semiconductor package 200 and/or the second semiconductor chip 300.

An external connection pad may be formed on a lower surface of the redistribution lower pad 122, and an external connection terminal 150 may be on the external connection pad. The external connection terminal 150 may be electrically connected to the sub-semiconductor package 200 and/or the second semiconductor chip 300 via the plurality of redistribution patterns 120 of the redistribution layer 100. The external connection terminal 150 may be configured to connect the semiconductor package 10 to a main board or the like of an electronic device, on which the semiconductor package 10 is mounted. The external connection pad may be a solder ball of a conductive material, e.g., a metal material including at least one of Sn, silver (Ag), Cu, and/or Al.

As shown in FIG. 1, the external connection pad and the external connection terminal 150 may be on a portion of the semiconductor package 10 corresponding to a lower surface of a semiconductor chip and on a portion of the semiconductor package 10 extending outward in a first horizontal direction (e.g., the X direction) and a second horizontal direction (e.g., the Y direction) from (or, e.g., beyond) the lower surface of the semiconductor chip. As a result, the redistribution layer 100 may redistribute a first connection terminal 250 of the sub-semiconductor package 200 as the external connection pad on a part wider than (or, e.g., beyond) a lower surface of the sub-semiconductor package 200.

The sub-semiconductor package 200 includes a sub-semiconductor package substrate 210 and the first semiconductor chip 220 stacked on the sub-semiconductor package substrate 210. Although FIG. 1 illustratively shows that one sub-semiconductor package 200 includes one first semiconductor chip 220, one sub-semiconductor package 200 may include a plurality of first semiconductor chips 220. In an embodiment of the present inventive concept, one sub-semiconductor package 200 may include first semiconductor chips 220 corresponding to a multiple of 4.

The sub-semiconductor package substrate 210 may include the plurality of first lower surface pads 212 and a plurality of first upper surface pads 214. The sub-semiconductor package substrate 210 may include a plurality of wiring paths electrically connecting the plurality of first lower surface pads 212 to the plurality of first upper surface pads 214 via a base board layer. In an embodiment of the present inventive concept, the sub-semiconductor package substrate 210 may be a printed circuit board. For example, the sub-semiconductor package substrate 210 may be a multi-layer printed circuit board.

For example, the sub-semiconductor package substrate 210 may be a land grid array (LGA) substrate. Therefore, the plurality of first lower surface pads 212 of the sub-semiconductor package substrate 210 may be in direct contact with and electrically and/or physically connected to the redistribution layer 100. For example, the plurality of first lower surface pads 212 of the sub-semiconductor package substrate 210 may be in direct contact with and electrically and/or physically connected to the plurality of conductive vias 128 of the redistribution layer 100. For example, the plurality of first lower surface pads 212 may be referred to as lead pins. For example, the sub-semiconductor package 200 may be an LGA package including an LGA substrate.

The plurality of first lower surface pads 212 and the plurality of first upper surface pads 214 may include, for example, Cu, Ni, stainless steel, or BeCu. For example, the plurality of first lower surface pads 212 and the plurality of first upper surface pads 214 may include plated Cu. In an embodiment of the present inventive concept, opposite surface parts of the plurality of first lower surface pads 212 and the plurality of first upper surface pads 214 may include Ni/gold (Au) or the like.

Each of the plurality of wiring paths may include a buried conductive layer and a conductive via. The plurality of wiring paths may include, for example, electrolytically deposited (ED) Cu, rolled-annealed (RA) Cu foil, stainless steel foil, Al foil, ultra-thin Cu foil, sputtered Cu, a Cu alloy, Ni, stainless steel, BeCu, or the like.

The base board layer may include at least one material selected from among, for example, a phenol resin, an epoxy resin, and polyimide. For example, the base board layer may include at least one material selected from among frame retardant 4 (FR4), tetrafunctional epoxy, polyphenylene ether, epoxy/polyphenylene oxide, bismaleimide triazine, Thermount, cyanate ester, polyimide, and a liquid crystal polymer. In an embodiment of the present inventive concept, the base board layer may include, for example, polyester, polyester terephthalate (PET), fluorinated ethylene propylene (FEP), resin-coated paper, a. liquid polyimide resin, a polyethylene naphthalate (PEN) film, or the like. The base board layer may be formed by stacking a plurality of base layers on each other.

The base board layer may further include a solder resist layer exposing the plurality of first lower surface pads 212 and the plurality of first upper surface pads 214 therethrough at lower and upper surfaces of the base board layer, respectively. The solder resist layer may include, for example, a polyimide film, a polyester film, a flexible solder mask, a photo-imageable coverlay (PIC), a photo-imageable solder resist, or the like. The solder resist layer may be formed by, for example, thermally curing thermosetting ink coated by silk screen printing or inkjet printing. The solder resist layer may be formed by removing a portion of a photo-imageable solder resist, which may be coated by screening or spray coating, by exposure and development and then thermally curing the remaining photo-imageable solder resist. The solder resist layer may be formed by laminating, for example, a polyimide film or a polyester film.

Redistribution patterns 120 of the redistribution layer 100 may be connected to the plurality of first lower surface pads 212, respectively, and a plurality of first connection terminals 250 may be electrically connected to the plurality of first upper surface pads 214, respectively. For example, the redistribution patterns 120 may be in direct contact with the plurality of first lower surface pads 212. For example, as described above, conductive vias 128 of the redistribution layer 100 may be connected to the plurality of first lower surface pads 212, respectively. For example, the conductive vias 128 may directly contact the first lower surface pads 212. The plurality of first connection terminals 250 may electrically connect the plurality of first upper surface pads 214 of the sub-semiconductor package substrate 210 to a plurality of second lower surface pads 224 of the first semiconductor chip 220, respectively.

The first semiconductor chip 220 may include one of, for example, dynamic random access memory (DRAM), static random access memory (SRAM), flash memory, electrically erasable and programmable read-only memory (EEPROM), phase-change random access memory (PRAM), magnetic random access memory (MRAM), and resistive random access Memory (RRAM). In an embodiment of the present inventive concept, the first semiconductor chip 220 may include one of, for example, a central processing unit (CPU) chip, a graphics processing unit (GPU) chip, an application processor (AP) chip, an application specific integrated circuit (ASIC), and other processing chips.

The first semiconductor chip 220 may include a first substrate 222 and the plurality of second lower surface pads 224. In an embodiment of the present inventive concept, the first semiconductor chip 220 may further include a plurality of second upper surface pads and a plurality of through electrodes on an inactive surface of the first semiconductor chip 220. The plurality of through electrodes may electrically connect the plurality of second lower surface pads 224 to the plurality of second upper surface pads, respectively.

The first substrate 222 may include, for example, silicon (Si). In addition, the first substrate 222 may include a semiconductor element, such as germanium (Ge), or a compound semiconductor, such as silicon carbide (SiC), gallium arsenide (GaAs), indium arsenide (InAs), or indium phosphide (InP). The first substrate 222 may have an active surface and an inactive surface opposite to the active surface. The first substrate 222 may include various types of a plurality of individual devices on the active surface thereof. The plurality of individual devices may include various microelectronics devices, e.g., metal-oxide-semiconductor field effect transistors (MOSFETs), such as complementary metal-oxide-semiconductor (CMOS) transistors, system (large scale integrations (LSIs), image sensors, such as CMOS imaging sensors (CISs), micro-electro-mechanical systems (MEMSs), active devices, passive devices, and the like. The first semiconductor chip 220 may include a first semiconductor device including at least one of the plurality of individual devices.

The first semiconductor device may be formed on the active surface of the first substrate 222, the plurality of second lower surface pads 224 and the plurality of second upper surface pads may be on the active surface and the inactive surface of the first substrate 222, respectively, and the plurality of through electrodes may electrically connect the plurality of second lower surface pads 224 to the plurality of second upper surface pads by vertically passing through at least portions of the first substrate 222, respectively.

The plurality of first connection terminals 250 may be respectively attached to the plurality of first upper surface pads 214 of the sub-semiconductor package substrate 210. The plurality of first connection terminals 250 may electrically connect the plurality of second lower surface pads 224 of the first semiconductor chip 22( )to the plurality of first upper surface pads 214 of the sub-semiconductor package substrate 210, respectively. Side surfaces of the plurality of first connection terminals 250 may be in direct contact with the molding layer 400. If the semiconductor package 10 is formed by a package-first method, the plurality of first connection terminals 250 might not need an underfill. If a plurality of first semiconductor chips 220 are stacked on each other, the plurality of first connection terminals 250 may be respectively attached to the plurality of second upper surface pads of the first semiconductor chip 220.

The second semiconductor chip 300 may include a second substrate 302 having a second semiconductor device formed on an active surface of the second substrate 302. The second semiconductor chip 300 may also include a plurality of third lower surface pads 304 on the active surface of the second substrate 302. The second substrate 302 is similar to the first substrate 222, and thus, a detailed description thereof is omitted herein. The plurality of third lower surface pads 304 may be referred to as chip pads. The plurality of redistribution patterns 120 of the redistribution layer 100 may be connected to the plurality of third lower surface pads 304. For example, the plurality of redistribution patterns 120 may be in direct contact with the plurality of third lower surface pads 304. For example, conductive vias 128 of the redistribution layer 100 may be in direct contact with and connected to the plurality of third lower surface pads 304, respectively. For example, the second semiconductor chip 300 may be a bumpless semiconductor chip. For example, the second semiconductor chip 300 may be connected to redistribution patterns 120 of the redistribution layer 100 by Cu-to-Cu bonding and/or hybrid bonding.

Under bump metallurgy (UBM) surrounding and protecting the plurality of third lower surface pads 304 may be on a lower surface of the second semiconductor chip 300.

The second semiconductor chip 300 may include one of, for example, a CPU chip, a GPU chip, an AP chip, an ASIC, and other processing chips. In an embodiment of the present inventive concept, the second semiconductor chip 300 may include one of, for example, DRAM, SRAM, flash memory, EEPROM, PRAM, MRAM, and RRAM.

A first thickness T1, which is a thickness of the sub-semiconductor package 200 in the vertical direction (e.g., the Z direction), may be approximately similar to a second thickness T2, which is a thickness of the second semiconductor chip 300 in the vertical direction (e.g., the Z direction). For example, the first thickness T1 and/or the second thickness T2 may be about 200 micrometers or greater. For example, the first thickness T1 and/or the second thickness T2 may be about 400 micrometers to about 800 micrometers.

The semiconductor package 10 may further include, on the redistribution layer 100, the molding layer 400 at least partially surrounding a side surface and/or an upper surface of each of the sub-semiconductor package 200 and the second semiconductor chip 300. The molding layer 400 may include, for example, an epoxy mold compound (EMC),

An upper surface of the molding layer 400 may be higher than a vertical level of each of the upper surface of the sub-semiconductor package 200 and the upper surface of the second semiconductor chip 300. The molding layer 400 may cover the upper surface of the sub-semiconductor package 200 and the upper surface of the second semiconductor chip 300.

According to an embodiment of the present inventive concept, the semiconductor package 10 may be manufactured by a chip-first method of first forming the sub-semiconductor package 200 and the second semiconductor chip 300 and then forming the redistribution layer 100. Therefore, the plurality of first connection terminals 250 of the sub-semiconductor package 200 may be in contact with the molding layer 400 without being surrounded by an underfill. In addition, the second semiconductor chip 300 may be in contact with the redistribution layer 100 by a bumpless method.

A general semiconductor package, according to a comparative example, is manufactured with a memory package and a logic semiconductor chip by a package-on-package method. According to the package-on-package method, a thickness in the vertical direction (e.g., the Z direction) is relatively large, and thus, a relatively large space is required to mount a semiconductor package.

However, the semiconductor package 10 according to an embodiment of the present inventive concept may have a relatively reduced thickness in the vertical direction (e.g., the Z direction) by arranging the sub-semiconductor package 200 and the second semiconductor chip 300 side-by-side (e.g., adjacent to each other). Therefore, the semiconductor package 10 having relatively high performance may be arranged in a relatively small space.

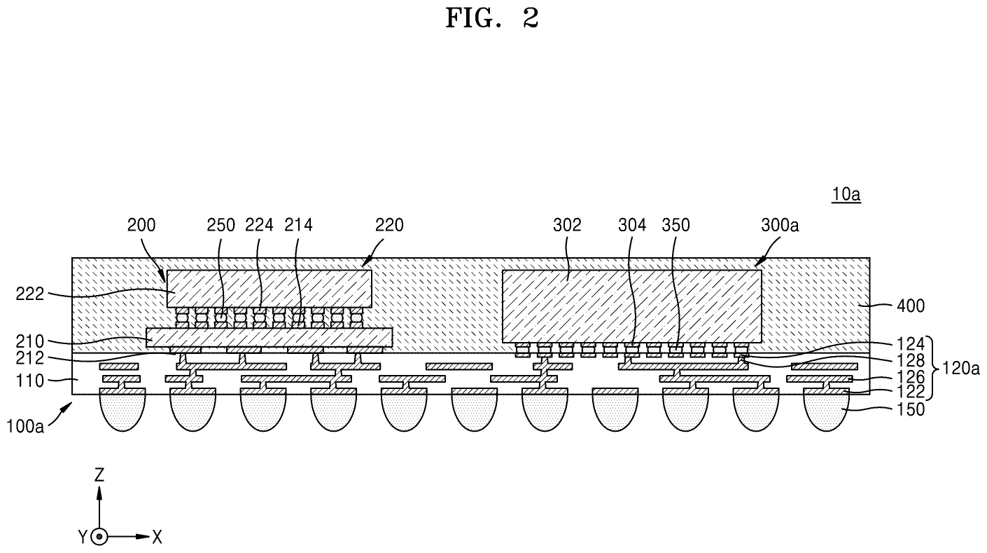

FIG. 2 is a cross-sectional view of a semiconductor package 10a according to an embodiment of the present inventive concept.

Referring to FIG. 2, the semiconductor package 10a may include a redistribution layer 100a, the sub-semiconductor package 200, a second semiconductor chip 300a, and the molding layer 400. The sub-semiconductor package 200 and the molding layer 400 of the semiconductor package 10a in FIG. 2 are substantially and respectively the same as the sub-semiconductor package 200 and the molding layer 400 of the semiconductor package 10 in FIG. 1, and thus, only the redistribution layer 100a and the second semiconductor chip 300a are described herein.

The redistribution layer 100a may further include, on an upper surface of the redistribution insulating layer 110, a plurality of redistribution upper surface pads 124. For example, the plurality of redistribution upper surface pads 124 may be electrically connected to some of the plurality of conductive vias 128, respectively. The plurality of redistribution upper surface pads 124 may be electrically connected to the plurality of second connection members (e.g., connection terminals) 350, respectively.

The second semiconductor chip 300a may include a plurality of third front pads 304. The plurality of second connection members 350 may be respectively attached to the plurality of third front pads 304 of the second semiconductor chip 300a, The plurality of third front pads 304 may be electrically respectively connected to the plurality of redistribution upper surface pads 124 of the redistribution layer 100a through the plurality of second connection members 350. The plurality of second connection members 350 may electrically connect the plurality of redistribution upper surface pads 124 of the redistribution layer 100a to the plurality of third front pads 304 of the second semiconductor chip 300, respectively. The second connection member 350 may be a solder ball made of a conductive material, e.g., a metal material including at least one of Sn, Ag, Cu, and/or Al.

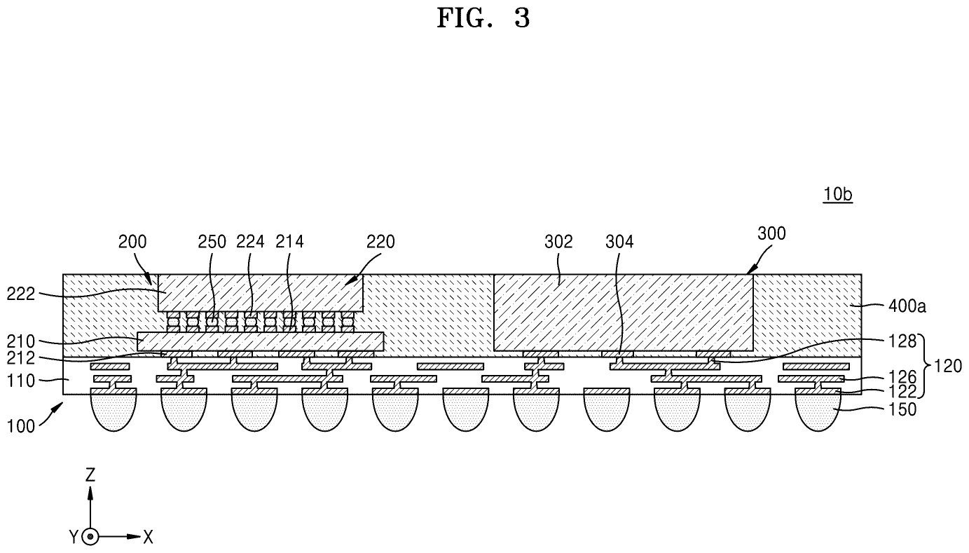

FIG. 3 is a cross-sectional view of a semiconductor package 10b according to an embodiment of the present inventive concept.

Referring to FIG. 3, the semiconductor package lob may include the redistribution layer 100, the sub-semiconductor package 200, the second semiconductor chip 300, and a molding layer 400a. The redistribution layer 100, the sub-semiconductor package 200, and the second semiconductor chip 300 of the semiconductor package 10b in FIG. 3 are substantially and respectively the same as the redistribution layer 100. the sub-semiconductor package 200, and the second semiconductor chip 300 of the semiconductor package 10 in FIG. 1, and thus, only the molding layer 400a is described herein.

The molding layer 400a may cover, while being disposed on the upper surface of the redistribution layer 100, the side surface of the sub-semiconductor package 200 and the side surface of the second semiconductor chip 300. An upper surface of the molding layer 400a may be at substantially the same vertical level as that of the upper surface of the sub-semiconductor package 200 and that of the upper surface of the second semiconductor chip 300. For example, the upper surface of the sub-semiconductor package 200 and the upper surface of the second semiconductor chip 300 might not be covered by the molding layer 400a.

If the upper surface of the molding layer 400a is at substantially the same vertical level as that of the upper surface of the sub-semiconductor package 200 and that of the upper surface of the second semiconductor chip 300, a thickness of the semiconductor package 10b in the vertical direction (e.g., the Z direction) may be reduced. In addition, if the upper surface of the molding layer 400a is at substantially the same vertical level as that of the upper surface of the sub-semiconductor package 200 and that of the upper surface of the second semiconductor chip 300, heat generated by each of the sub-semiconductor package 200 and the second semiconductor chip 300 may be easily discharged to the outside of the semiconductor package 10b.

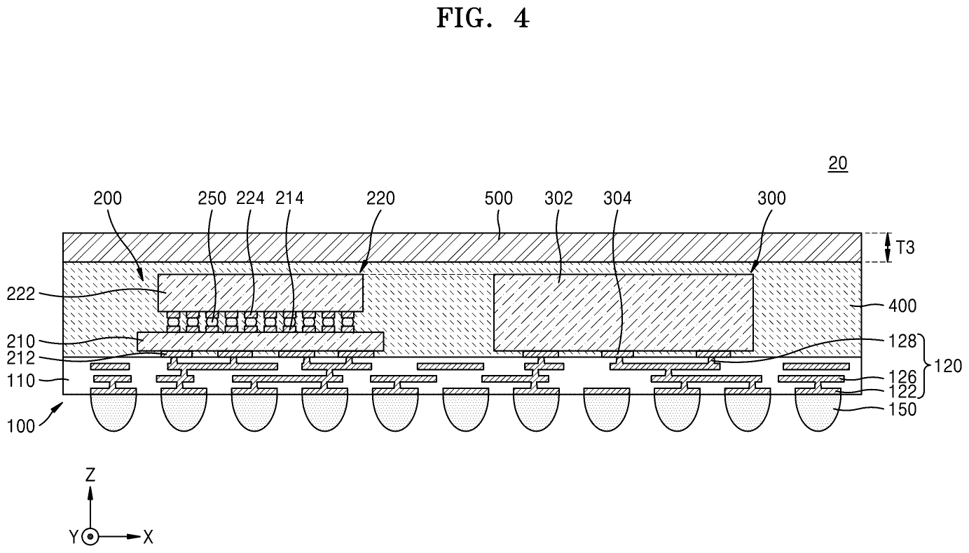

FIG. 4 is a cross-sectional view of a semiconductor package 20 according to an embodiment of the present inventive concept.

Referring to FIG. 4, the semiconductor package 20 may include the redistribution layer 100, the sub-semiconductor package 200, the second semiconductor chip 300, the molding layer 400, and a lead 500. The redistribution layer 100, the sub-semiconductor package 200, the second semiconductor chip 300, and the molding layer 400 of the semiconductor package 20 in FIG. 4 are substantially and respectively the same as the redistribution layer 100, the sub-semiconductor package 200, the second semiconductor chip 300, and the molding layer 400 of the semiconductor package 10 in FIG. 1, and thus, only the lead 500 is described herein,

The lead 500 may be attached onto the semiconductor package 10 of FIG. 1. For example, the lead 500 may be disposed on an upper surface of the semiconductor package 10 of FIG. 1. The lead 500 may be attached onto the sub-semiconductor package 200 and the second semiconductor chip 300. The lead 500 may include, for example, a heat sink, a heat spreader, a heat pipe, and/or a liquid cooled cold plate. For example, the lead 500 may include a metal, such as Cu, Ni, Au, Ag, Al, W, Ti, Ta, In, Mo, Mn, Co, Sn, Mg, Re, Be, Ga, or Ru, or an alloy thereof.

For example, a third thickness T3, which is a thickness of the lead 500 in the vertical direction (e.g., the Z direction), may be about 100 micrometers or greater. For example, the third thickness T3, which is the thickness of the lead 500 in the vertical direction (e.g., the Z direction), may be about 100 micrometers to about 300 micrometers.

The molding layer 400 may be disposed between the lead 500 and the sub-semiconductor package 200 and between the lead 500 and the second semiconductor chip 300. An adhesive layer may be disposed between the lead 500 and the molding layer 400 so that they may adhere to each other. For example, the adhesive layer may include a thermal interface material (TIM).

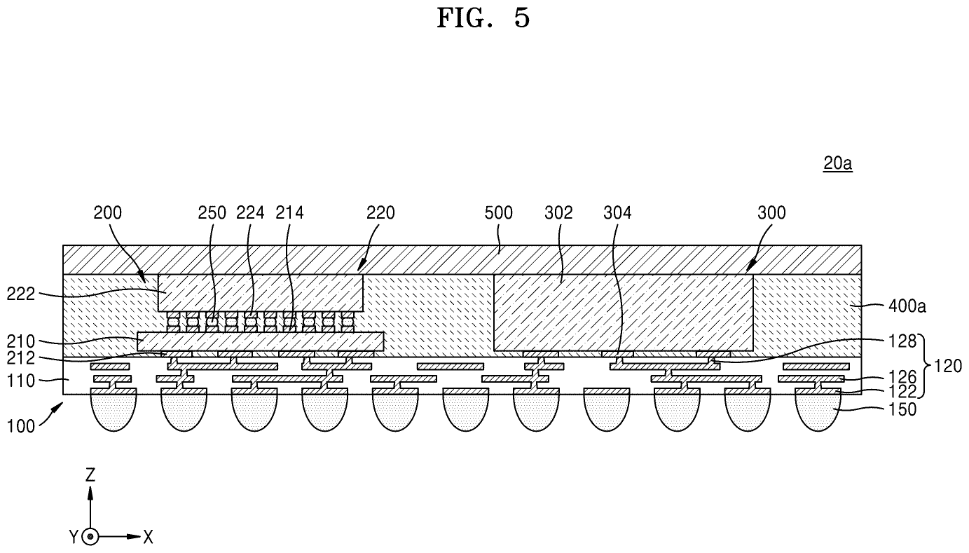

FIG. 5 is a cross-sectional view of a semiconductor package 20a according to an embodiment of the present inventive concept.

The semiconductor package 20a of FIG. 5 may include the redistribution layer 100, the sub-semiconductor package 200, the second semiconductor chip 300, the molding layer 400a, and the lead 500. The redistribution layer 100, the sub-semiconductor package 200, the second semiconductor chip 300, and the lead 500 of the semiconductor package 20a in FIG. 5 may be substantially and respectively the same as the redistribution layer 100, the sub-semiconductor package 200, the second semiconductor chip 300, and the lead 500 of the semiconductor package 20 in FIG. 4, and the molding layer 400a of the semiconductor package 20a in FIG. 5 may be substantially the same as the molding layer 400a of FIG. 3.

Referring to FIG. 5, the molding layer 400a may cover, while being disposed on the upper surface of the redistribution layer 100, the side surface of the sub-semiconductor package 200 and the side surface of the second semiconductor chip 300. The upper surface of the molding layer 400a may be at substantially the same vertical level as that of the upper surface of the sub-semiconductor package 200 and that of the upper surface of the second semiconductor chip 300. For example, the upper surface of the sub-semiconductor package 200 and the upper surface of the second semiconductor chip 300 might not be covered by the molding layer 400a.

The lead 500 may be attached onto the sub-semiconductor package 200 and the second. semiconductor chip 300. In addition, the lead 500 may be disposed on the molding layer 400a. A lower surface of the lead 500 may be at substantially the same vertical level as that of each of the upper surface of the molding layer 400a, the upper surface of the sub-semiconductor package 200, and the upper surface of the second semiconductor chip 300.

If the lower surface of the lead 500 is at substantially the same vertical level as that of each of the upper surface of the molding layer 400a, the upper surface of the sub-semiconductor package 200, and the upper surface of the second semiconductor chip 300, heat generated from the upper surface of the sub-semiconductor package 200 and the upper surface of the second semiconductor chip 300 may be easily discharged to the outside of the semiconductor package 20a. For example, a heat-dissipating characteristic of the semiconductor package 20a may be improved.

As described above, if an adhesive layer is on the molding layer 400a, the lower surface of the lead 500 may be at a higher vertical level than that of each of the upper surface of the molding layer 400a, the upper surface of the sub-semiconductor package 200, and the upper surface of the second semiconductor chip 300.

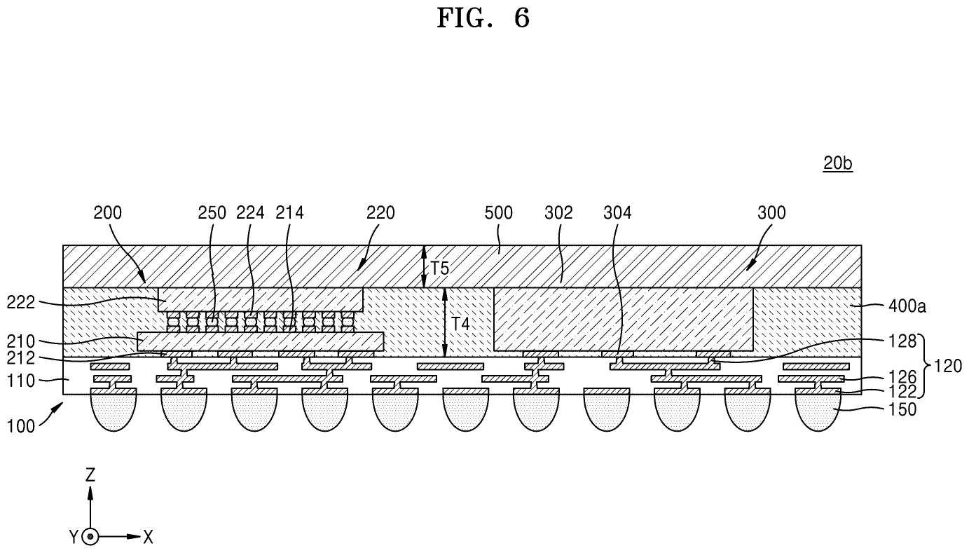

FIG. 6 is a cross-sectional view of a semiconductor package 20b according to an embodiment of the present inventive concept.

Referring to FIG. 6, a fourth thickness T4, which is a thickness of each of the sub-semiconductor package 200 and the second semiconductor chip 300 in the vertical direction (e.g., the Z direction), may be reduced, and a fifth thickness 15, which is a thickness of the lead 500 in the vertical direction (e.g., the Z direction) may be increased. For example, the fifth thickness T5 is bigger than the third thickness T3 in FIG. 4. For example, the fourth thickness T4 may be about 300 micrometers to about 700 micrometers. For example, the fifth thickness T5 may be about 200 micrometers to about 400 micrometers. If the thickness of the lead 500 in the vertical direction (e.g., the Z direction) is increased, heat generated from the upper surface of the sub-semiconductor package 200 and the second semiconductor chip 300 may be easily discharged to the outside of the semiconductor package 20b. For example, a heat-dissipating characteristic of the semiconductor package 20b may be improved.

A thickness of the molding layer 400a in the vertical direction (e.g., the Z direction) may be approximately similar to the fourth thickness T4, which is the thickness of each of the sub-semiconductor package 200 and the second semiconductor chip 300 in the vertical direction (e.g., the Z direction). Therefore, the thickness of the molding layer 400a in the vertical direction (e.g., the Z direction) may also be reduced.

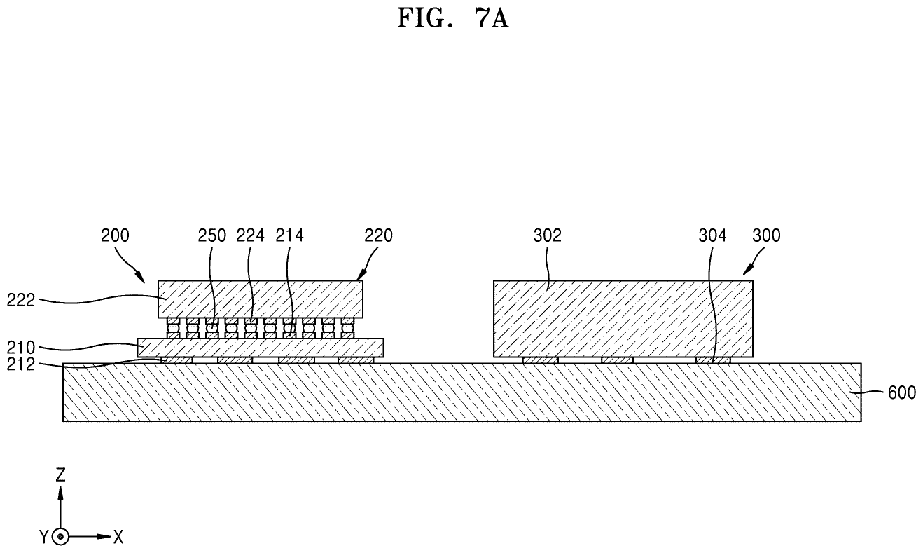

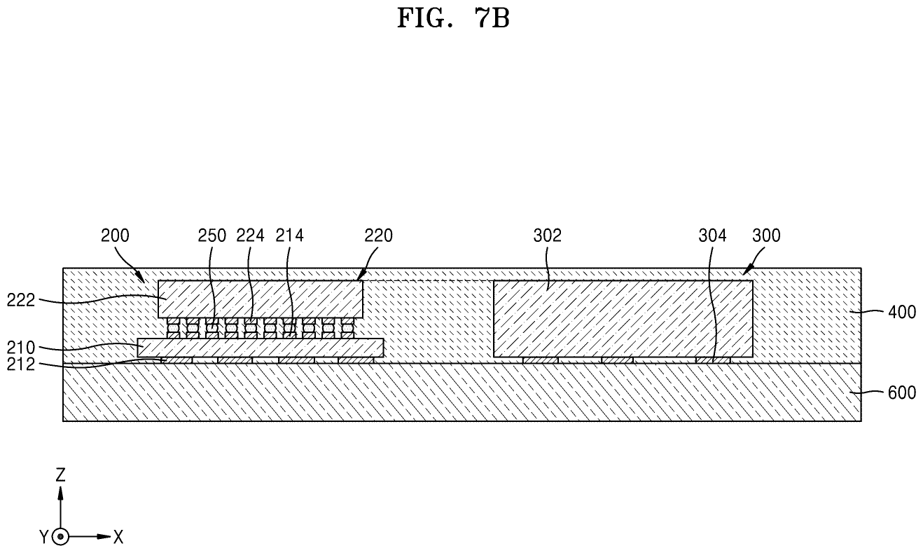

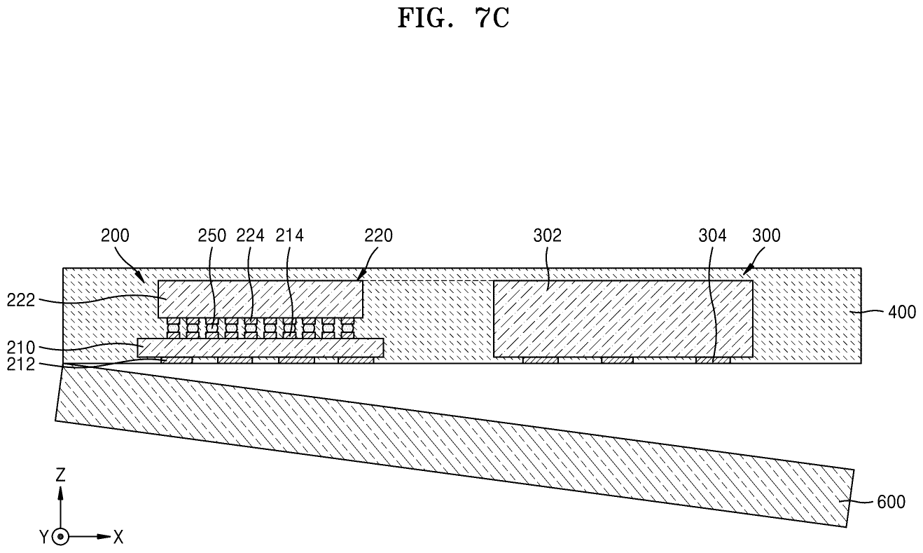

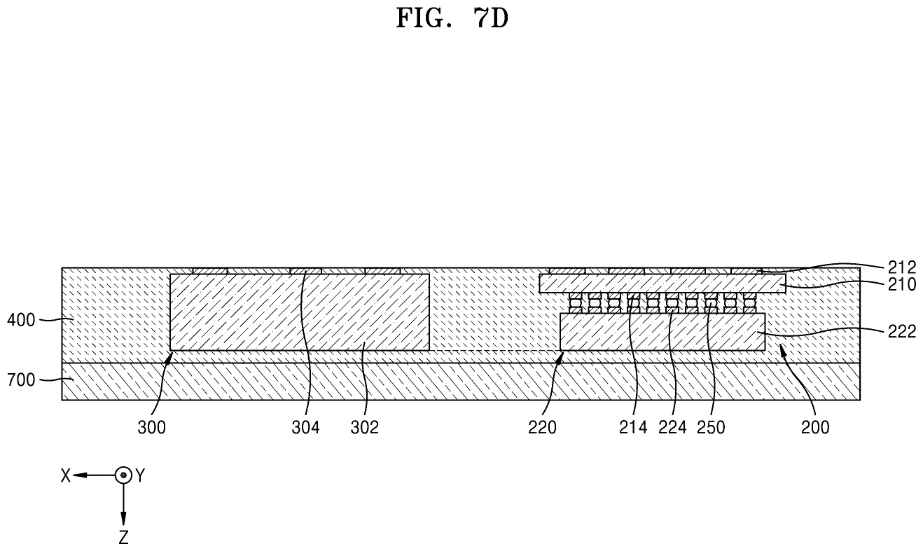

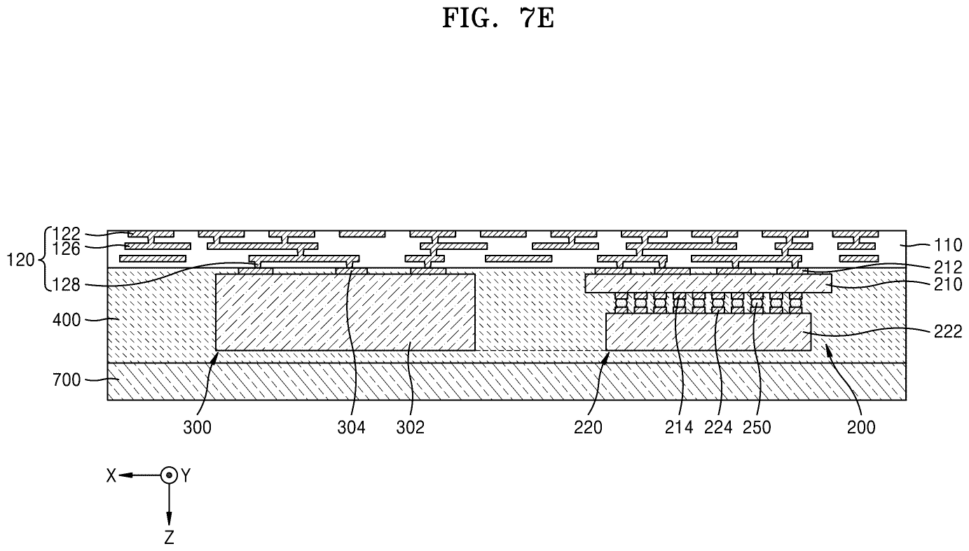

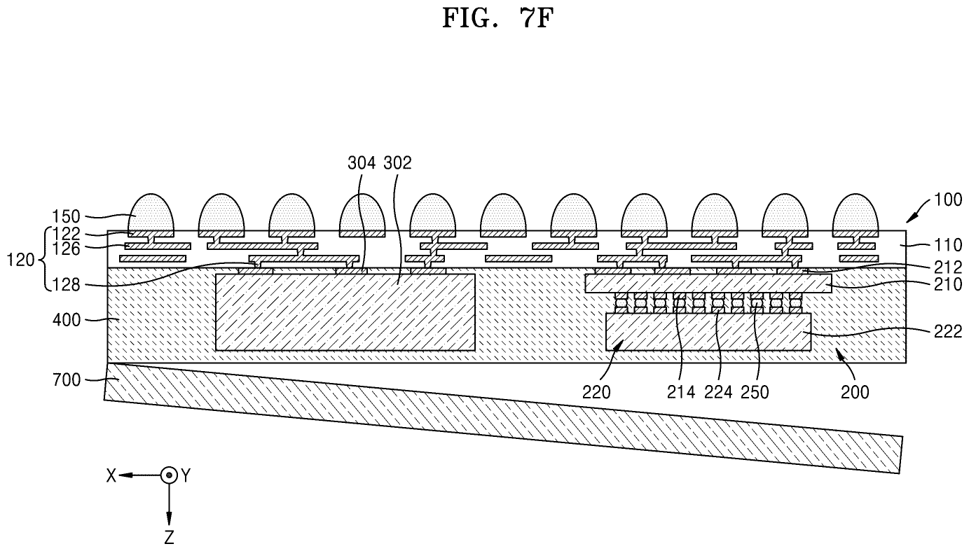

FIGS. 7A to 7F are cross-sectional views illustrating a method of forming a semiconductor package, according to an embodiment of the present inventive concept. Particularly, FIGS. 7A to 7F are cross-sectional views illustrating a method of manufacturing the semiconductor package 10 of FIG. 1.

Referring to FIG. 7A, the sub-semiconductor package 200 and the second semiconductor chip 300 are prepared on a first support carrier 600. The sub-semiconductor package 200 may include the sub-semiconductor package substrate 210 and the first semiconductor chip 220 stacked on the sub-semiconductor package substrate 210. The sub-semiconductor package substrate 210 may be, for example, an LGA substrate. The second semiconductor chip 300 may include the second substrate 302 and the plurality of third lower surface pads 304.

Referring to FIG. 7B, the molding layer 400 may be formed on the first support carrier 600. The molding layer 400 may cover the side surface and the upper surface of each of the sub-semiconductor package 200 and the second semiconductor chip 300. Thereafter, an upper part of the molding layer 400 may be partially grounded.

Referring to FIG. 7C, the first support carrier 600 may be removed.

Referring to FIG. 7D, the sub-semiconductor package 200 and the second semiconductor chip 300 may be turned upside down, and then a second support carrier 700 may be attached to an upper surface of the molding layer 400.

Referring to FIG. 7E, the redistribution layer 100 may be formed on the result (e.g., a resulting structure) shown in FIG. 7D. The redistribution layer 100 may include the redistribution insulating layer 110 and the plurality of redistribution patterns 120. Each of the plurality of redistribution patterns 120 may include the redistribution lower pad 122, the redistribution line pattern 126, and the conductive via 128. The plurality of redistribution patterns 120 may be disposed on the plurality of first lower surface pads 212 of the sub-semiconductor package 200 and the plurality of third lower surface pads 304 of the second semiconductor chip 300. For example, the plurality of redistribution patterns 120 may be in direct contact with the plurality of first lower surface pads 212 of the sub-semiconductor package 200 and the plurality of third lower surface pads 304 of the second semiconductor chip 300. For example, the plurality of conductive vias 128 may be in direct contact with the plurality of first lower surface pads 212 of the sub-semiconductor package 200 and the plurality of third lower surface pads 304 of the second semiconductor chip 300.

Referring to FIG. 7F, the second support carrier 700 may be removed. In addition, the external connection terminal 150 may be disposed on the redistribution lower pad 122 of the redistribution layer 100.

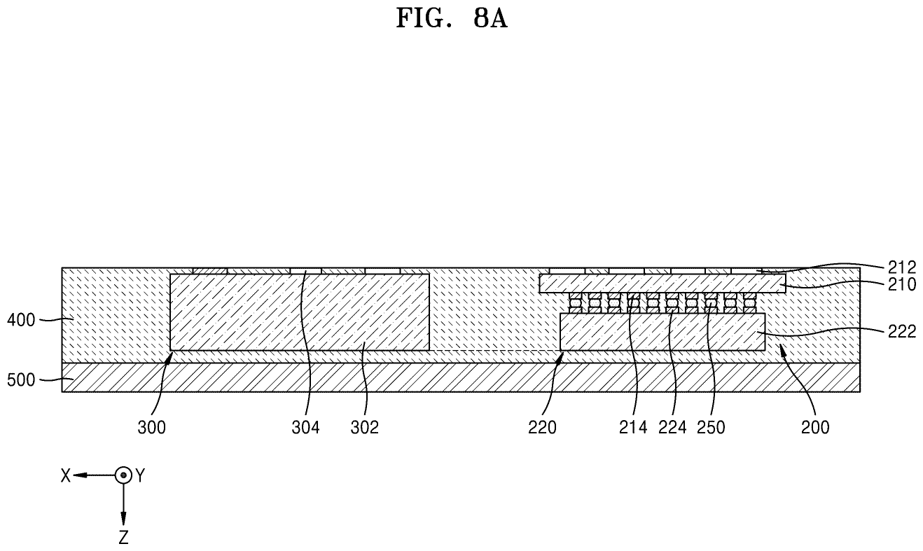

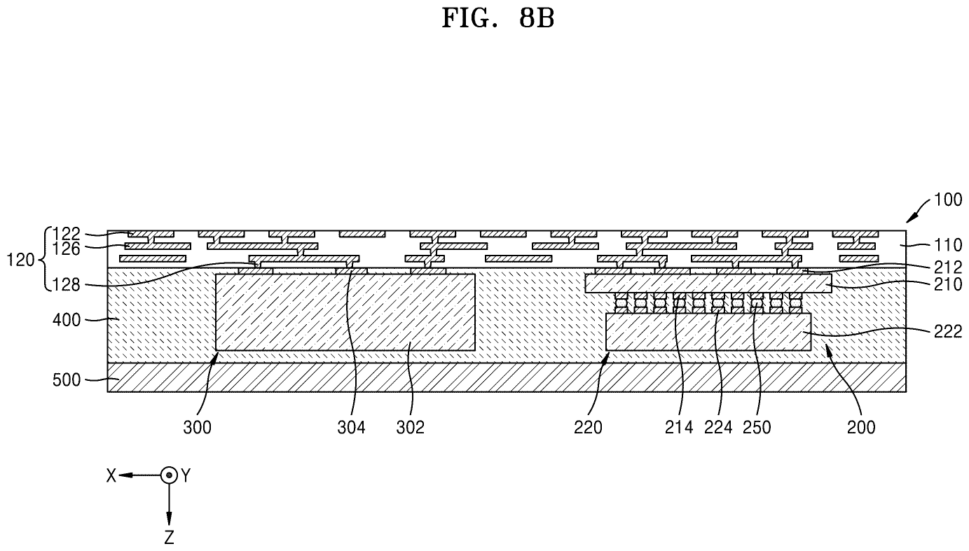

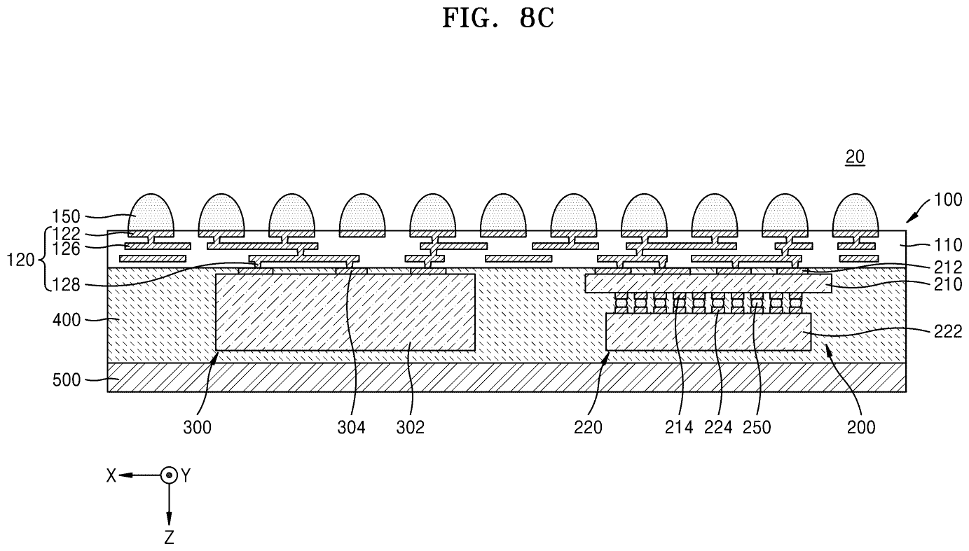

FIGS. 8A to 8C are cross-sectional views illustrating a method of manufacturing a semiconductor package, according to an embodiment of the present inventive concept. Particularly, FIGS. 8A to 8C are cross-sectional views illustrating a method of manufacturing the semiconductor package 20 of FIG. 4.

Referring to FIG. 8A, from the result (e.g., a resulting structure) of FIG. 7C, the first support carrier 600 may be removed, the sub-semiconductor package 200 and the second semiconductor chip 300 may be turned upside down, and then the lead 500 may be attached to the upper surface of the molding layer 400. For example, the lead 500 may include a metal, such as Cu, Ni, Au, Ag, Al, W, Ti, Ta, In, Mo, Mn, Co, Sn, Mg, Re, Be, Ga, or Ru, or an alloy thereof.

Referring to FIG. 8B, the redistribution layer 100 may be formed on the result (e.g., resulting structure) of FIG. 8A. The redistribution layer 100 may include the redistribution insulating layer 110 and the plurality of redistribution patterns 120. Each of the plurality of redistribution patterns 120 may include the redistribution lower pad 122, the redistribution line pattern 126, and the conductive via 128. For example, the plurality of redistribution patterns 120 may be in direct contact with the plurality of first lower surface pads 212 of the sub-semiconductor package 200 and the plurality of third lower surface pads 304 of the second semiconductor chip 300. For example, the plurality of conductive vias 128 may be in direct contact with the plurality of first lower surface pads 212 of the sub-semiconductor package 200 and the plurality of third lower surface pads 304 of the second semiconductor chip 300.

Referring to FIG. 8C, the external connection terminal 150 may be formed on the redistribution lower pad 122 of the redistribution layer 100. The external connection terminal 150 may be disposed to form the semiconductor package 20.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package comprising:
a redistribution layer comprising a plurality of redistribution patterns;
a sub-semiconductor package comprising a sub-semiconductor package substrate and a first semiconductor chip that is on the sub-semiconductor package substrate, wherein the sub-semiconductor package substrate is on the redistribution layer and comprises a plurality of first lower surface pads; and
a second semiconductor chip on the redistribution layer and spaced apart from the sub-semiconductor package in a horizontal direction, wherein the second semiconductor chip comprises a chip pad,
wherein at least some of the plurality of redistribution patterns of the redistribution layer are in direct contact with and electrically connected to the plurality of first lower surface pads of the sub-semiconductor package, respectively.

2. The semiconductor package of claim 1, wherein the sub-semiconductor package substrate comprises a land grid array (LGA) substrate.

3. The semiconductor package of claim 1, wherein the chip pad of the second semiconductor chip is in direct contact with and electrically connected to at least some of the plurality of redistribution patterns of the redistribution layer.

4. The semiconductor package of claim 1, wherein the redistribution layer further comprises: a redistribution upper surface pad, and the semiconductor package further comprises a connection terminal between the chip pad of the second semiconductor chip and the redistribution upper surface pad.

5. The semiconductor package of claim 1, wherein a thickness of the sub-semiconductor package in a vertical direction is substantially the same as a thickness of the second semiconductor chip in the vertical direction.

6. The semiconductor package of claim 1, wherein the first semiconductor chip comprises a memory semiconductor chip, and the second semiconductor chip comprises a logic semiconductor chip.

7. A semiconductor package comprising:
a redistribution layer comprising a plurality of redistribution patterns;
a sub-semiconductor package comprising a sub-semiconductor package substrate and a first semiconductor chip that is on the sub-semiconductor package substrate and that comprises a plurality of second lower surface pads, wherein the sub-semiconductor package substrate is on the redistribution layer and comprises a plurality of first lower surface pads and a plurality of first upper surface pads;
a second semiconductor chip on the redistribution layer and spaced apart from the sub-semiconductor package in a horizontal direction, wherein the second semiconductor chip comprises a plurality of third lower surface pads; and
a molding layer on the redistribution layer and at least partially surrounding a side surface of each of the sub-semiconductor package and the second semiconductor chip,
wherein at least some of the plurality of redistribution patterns of the redistribution layer are in direct contact with and electrically connected to the plurality of first lower surface pads of the sub-semiconductor package, respectively.

8. The semiconductor package of claim 7, wherein the sub-semiconductor package comprises a land grid array (LGA) package comprising an LGA substrate.

9. The semiconductor package of claim 7, wherein an upper surface of the molding layer is at a higher vertical level than that of each of an upper surface of the sub-semiconductor package and an upper surface of the second semiconductor chip.

10. The semiconductor package of claim 7, wherein an upper surface of the molding layer is at substantially the same vertical level as that of each of an upper surface of the sub-semiconductor package and an upper surface of the second semiconductor chip.

11. The semiconductor package of claim 7, further comprising a lead on the sub-semiconductor package and the second semiconductor chip.

12. The semiconductor package of claim 11, wherein a lower surface of the lead is at substantially the same vertical level as that of an upper surface of the molding layer, and is at a higher vertical level than that of each of an upper surface of the sub-semiconductor package and an upper surface of the second semiconductor chip.

13. The semiconductor package of claim 11, wherein a lower surface of the lead is at substantially the same vertical level as that of each of an upper surface of the molding layer,
an upper surface of the sub-semiconductor package, and an upper surface of the second semiconductor chip.

14. A semiconductor package comprising:
a redistribution layer comprising a plurality of redistribution lower pads, a plurality of redistribution line patterns, and a plurality of conductive vias;
a sub-semiconductor package comprising a sub-semiconductor package substrate and a first semiconductor chip that is on the sub-semiconductor package substrate and that comprises a plurality of second lower surface pads, wherein the sub-semiconductor package substrate is on the redistribution layer and comprises a plurality of first lower surface pads and a plurality of first upper surface pads;
a plurality of first connection terminals between the plurality of first upper surface pads and the plurality of second lower surface pads;
a second semiconductor chip on the redistribution layer and spaced apart from the sub-semiconductor package in a horizontal direction, wherein the second semiconductor chip comprises a plurality of third lower surface pads; and
a molding layer on the redistribution layer and at least partially surrounding a side surface of each of the sub-semiconductor package and the second semiconductor chip,
wherein at least some of the plurality of conductive vias of the redistribution layer are in direct contact with and electrically connected to the plurality of first lower surface pads of the sub-semiconductor package, respectively, and wherein the sub-semiconductor package comprises a land grid array (LGA) substrate.

15. The semiconductor package of claim 14, wherein side surfaces of the plurality of first connection terminals are in direct contact with the molding layer.

16. The semiconductor package of claim 14, wherein the molding layer surrounds an upper surface of each of the sub-semiconductor package and the second semiconductor chip.

17. The semiconductor package of claim 14, wherein the redistribution layer further comprises: a plurality of redistribution upper surface pads, and the semiconductor package further comprises a plurality of second connection terminals between the plurality of third lower surface pads of the second semiconductor chip and the plurality of redistribution upper surface pads.

18. The semiconductor package of claim 14, further comprising a lead on the sub-semiconductor package, the second semiconductor chip, and the molding layer.

19. The semiconductor package of claim 18, wherein a thickness of the lead in a vertical direction is about 100 micrometers to about 300 micrometers.

20. The semiconductor package of claim 14, wherein a thickness of each of the sub-semiconductor package and the second semiconductor chip in a vertical direction is about 200 micrometers to about 800 micrometers.
